(19) United States
(12) Patent Application Publication
(10) Pub. No.: US 2017/0084854 A1
(43) Pub. Date: Mar. 23, 2017

(54) LIGHT EMITTING DEVICE

(71) Applicant: SHENZHEN CHINA STAR OPTOELECTRONICS TECHNOLOGY CO., LTD., GUANGDONG (CN)

(72) Inventor: Kaifeng ZHOU, Guangdong (CN)

(21) Appl. No.: 14/890,593

(22) PCT Filed: Sep. 28, 2015
(86) PCT No.: PCT/CN2015/090938

§ 371 Date: Nov. 12, 2015

(30) Foreign Application Priority Data
Sep. 23, 2015 (CN) 201510610929.0

(51) Int. Cl. H01L 51/50

(52) U.S. Cl. CPC H01L 51/504; H01L 51/5092; H01L 51/5072; H01L 51/5088; H01L 51/5056

(57) ABSTRACT

A white light emitting diode device includes a substrate, a blue light source generating panel and a photoluminescent layer. The blue light source generating panel is disposed on a first surface of the substrate. The blue light source generating panel is used for generating blue light. The photoluminescent layer is disposed on a second surface of the substrate. The photoluminescent layer is used for generating white light when the photoluminescent layer is irradiated by the blue light.

### BACKGROUND OF THE INVENTION

1. Field of the Invention

The present invention relates to a light source, and particularly to a light emitting device.

2. Description of the Related Art

A White Organic Light Emitting Diode (WOLED) can be used as a light source applied in a lighting field or a display field.

A WOLED is generally divided into two types: a WOLED with a single light-emitting layer and a WOLED with multiple light-emitting layers. A WOLED with a single light-emitting layer generally achieves mixed white light by doping differently colored light emitting materials with predetermined concentrations into the light-emitting layer. It is difficult to control the doping concentrations of the light-emitting materials in the WOLED with a single light-emitting layer; interference exists between the differently colored light-emitting material; whereby it is difficult to obtain pure white light. A WOLED with multiply light-emitting layers generally generates white light through three stacked red, green and blue light-emitting materials. A mixture of the three colored light obtains the white light. Manufacture of the WOLED with multiple light-emitting layers is complicated. The differently colored light emitting materials in different layers will absorb energy from each other, resulting in a reduced lighting efficiency.

In summary, the manufacture of a traditional WOLED is complicated, the lighting efficiency thereof is not high, and the quality of the white light obtained thereby is not good enough.

Thus, it is necessary to provide a new technical solution which can solve the problems mentioned above.

### SUMMARY OF THE INVENTION

The present invention aims to provide a light emitting device which can be manufactured through a simpler process, and has a higher luminous stability and a longer life.

To solve the problems mentioned above, the technical solution of the present invention is as follows:

A light emitting device is provided, which comprises a substrate, the substrate comprising a first surface and a second surface; a blue light source generating panel, the blue light source generating panel being disposed on the first surface, the blue light source generating panel being used for generating blue light; a photoluminescent layer, the photoluminescent layer being disposed on the second surface, the photoluminescent layer being used for generating white light when the photoluminescent layer is irradiated by the blue light; the blue light source generating panel comprising: an anode layer, a cathode layer, and an electroluminescent blue light emitting material layer, the electroluminescent blue light emitting material layer being disposed between the anode layer and the cathode layer, the electroluminescent blue light emitting material layer being used for generating the blue light when there is a predetermined voltage difference between the anode layer and the cathode layer; and a power supply being used for applying a voltage to the anode layer and the cathode layer to form the predetermined voltage difference between the anode layer and the cathode layer; the blue light source generating panel further comprising: a hole injection layer, a hole transport layer, an electronic transport layer, and an electronic injection layer, wherein the hole injection layer is disposed between the anode layer and the hole transport layer, the electroluminescent blue light emitting material layer is disposed between the hole transport layer and the electronic transport layer, the electronic injection layer is disposed between the electronic transport layer and the cathode layer; the photoluminescent layer comprises: a body material, the body material being used for enabling the blue light to pass therethrough when the blue light irradiates the body material; a photoluminescent green light emitting material, the photoluminescent green light emitting material being used for emitting green light when it is irradiated by the blue light; and a photoluminescent red light emitting material, the photoluminescent red light emitting material being used for emitting red light when it is irradiated by the blue light.

In the aforementioned light emitting device, the photoluminescent green light emitting material is disposed in the body material in a form of rectangular blocks or round granules; the photoluminescent red light emitting material is disposed in the body material in a form of rectangular blocks or round granules.

In the aforementioned light emitting device, the photoluminescent layer comprises a first stratification, the photoluminescent green light emitting material, the photoluminescent red light emitting material, and the body material all being located in the first stratification.

In the aforementioned light emitting device, a combination of the photoluminescent green light emitting material and the photoluminescent red light emitting material is arranged in a form of a one-dimensional array or a two-dimensional array.

In the aforementioned light emitting device, there is a gap between the photoluminescent green light emitting material and the photoluminescent red light emitting material, and the gap is filled by the body material.

In the aforementioned light emitting device, the photoluminescent green light emitting material and the photoluminescent red light emitting material are randomly mixed in the body material.

In the aforementioned light emitting device, the photoluminescent layer comprises a second stratification and a third stratification, the photoluminescent green light emitting material being located in the second stratification, the photoluminescent red light emitting material being located in the third stratification, and the body material being disposed in the second stratification and the third stratification.

A light emitting device comprises a substrate, the substrate including a first surface and a second surface; a blue light source generating panel, the blue light source generating panel being disposed on the first surface, the blue light source generating panel being used for generating blue light; a photoluminescent layer, the photoluminescent layer being disposed on the second surface, the photoluminescent layer being used for generating white light when it is irradiated by the blue light.

In the aforementioned light emitting device, the blue light source generating panel comprises an anode layer, a cathode layer and an electroluminescent blue light emitting material layer; the electroluminescent blue light emitting material layer being disposed between the anode layer and the cathode layer, the electroluminescent blue light emitting material layer being used for generating the blue light when there is a predetermined voltage difference between the anode layer and the cathode layer, and a power supply being used for applying a voltage to the anode layer and the cathode layer to form the predetermined voltage difference between the anode layer and the cathode layer.

In the aforementioned light emitting device, the blue light source generating panel further comprises a hole injection layer, a hole transport layer, an electronic transport layer, and an electronic injection layer, wherein the hole injection layer is disposed between the anode layer and the hole transport layer, the electroluminescent blue light emitting material layer is disposed between the hole transport layer and the electronic transport layer, and the electronic injection layer is disposed between the electronic transport layer and the cathode layer.

In the light emitting device aforementioned, the photoluminescent layer comprises a body material, the body material being used for enabling the blue light to pass therethrough; a photoluminescent green light emitting material, the photoluminescent green light emitting material being used for emitting green light when it is irradiated by the blue light; and a photoluminescent red light emitting material, the photoluminescent red light emitting material being used for emitting red light when it is irradiated by the blue light.

In the light emitting device aforementioned, the photoluminescent layer is used for enabling the generated red light and green light and the blue light passing therethrough to mix together to form the white light.

In the aforementioned light emitting device, the photoluminescent green light emitting material is disposed in the body material in a form of rectangular blocks or round granules; the photoluminescent red light emitting material is disposed in the body material in a form of rectangular block or round granules.

In the aforementioned light emitting device, the photoluminescent layer comprises a first stratification, the photoluminescent green light emitting material, the photoluminescent red light emitting material, and the body material all being located in the first stratification.

In the aforementioned light emitting device, a combination of the photoluminescent green light emitting material and the photoluminescent red light emitting material is arranged in a form of a one-dimensional array or a two-dimensional array.

In the light emitting device aforementioned, there is a gap between the photoluminescent green light emitting material and the photoluminescent red light emitting material, and the body material fills the gap.

In the aforementioned light emitting device, the photoluminescent green light emitting material and the photoluminescent red light emitting material are randomly mixed in the body material.

In the aforementioned light emitting device, the photoluminescent layer comprises a second stratification and a third stratification; the photoluminescent green light emitting material being located in the second stratification, the photoluminescent red light emitting material being located in the third stratification, and the body material being disposed in the second stratification and the third stratification.

In the aforementioned light emitting device, the photoluminescent layer is located on a plane; a sum of a projected area of the photoluminescent green light emitting material to the plane is a first area; a sum of a projected area of the photoluminescent red light emitting material to the plane is a second area; a sum of a projected area of the transparent body material to the plane is a third area, wherein any one of the first area, the second area, the third area equals to another one of the first area, the second area, the third area multiplies a predetermined ratio; the predetermined ratio is in a range from 90% to 110%.

In the aforementioned light emitting device, the first area equals the second area which in turn equals the third area.

Compared to the prior art, the light emitting device of the present invention can be manufactured through a simpler process, and has a higher luminous stability and a longer life.

### BRIEF DESCRIPTION OF THE DRAWINGS

The accompanying drawings are included to provide a further understanding of the invention, and are incorporated into, and constitute a part of, this specification. The drawings illustrate embodiments of the invention and, together with the description, serve to explain the principles of the invention.

FIG. 1 illustrates a diagram, in cross section, of a first embodiment of the light emitting device of the present invention;

FIG. 2 illustrates a diagram, in cross section, of a second embodiment of the light emitting device of the present invention;

FIG. 3 illustrates a diagram, in a plan view, of a first embodiment of the photoluminescent layer in FIG. 1 or FIG. 2;

FIG. 4 illustrates a cross-sectional view of the photoluminescent layer of FIG. 3, taken along line A-A′ thereof;

FIG. 5 illustrates a cross-sectional view of the photoluminescent layer of FIG. 3, taken along line A-A′ thereof, showing an alternative embodiment;

FIG. 6 illustrates a diagram, in a plain view, of a second embodiment of the photoluminescent layer in FIG. 1 or FIG. 2; and

FIG. 7 illustrates a diagram, in a plain view, of a third embodiment of the photoluminescent layer in FIG. 1 or FIG. 2.

### DESCRIPTION OF THE EMBODIMENTS

As used in this specification the term “embodiment” means an instance, an example, or an illustration. In addition, for the articles in this specification and the appended claims, “a” or “an” in general can be interpreted as “one or more” unless specified otherwise or clear from context to determine the singular form.

The light emitting device of the present invention can be an organic light emitting diode (OLED) and in particular can be a White Organic Light Emitting Diode (WOLED). The light emitting device is used for generating white light. The white light generated by the light emitting device can be used for illumination, or used as a backlight source of a display panel.

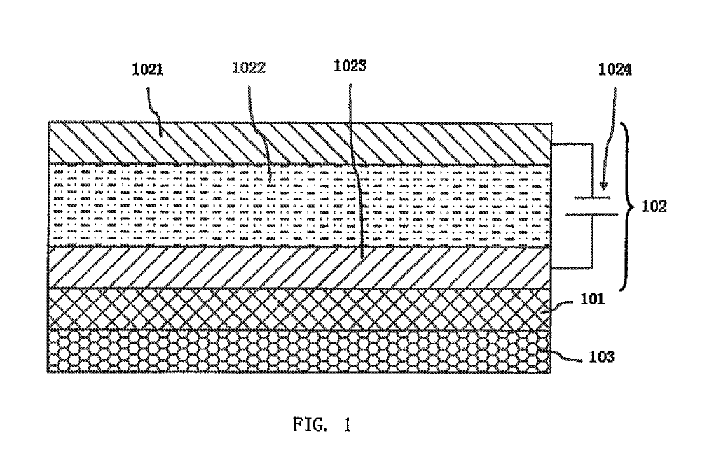

Refer to FIG. 1, which illustrates a diagram, in cross section, of a first embodiment of the light emitting device of the present invention.

The light emitting device of the embodiment includes a substrate 101, a blue light source generating panel 102, and a photoluminescent layer 103.

The substrate 101 includes a first surface and a second surface.

The blue light source generating panel 102 is disposed on the first surface, and the blue light source generating panel 102 is used for generating blue light.

The photoluminescent layer 103 is disposed on the second surface, and the photoluminescent layer 103 is used for generating white light when the photoluminescent layer 103 is irradiated by the blue light.

In the embodiment, the blue light source generating panel 102 includes an anode layer 1023, a cathode layer 1021, an electroluminescent blue light emitting material layer 1022, and a power supply 1024.

The anode layer 1023 is disposed on the first surface of the substrate 101. The electroluminescent blue light emitting material layer 1022 is disposed between the anode layer 1023 and the cathode layer 1021. The electroluminescent blue light emitting material layer 1022 is used for generating the blue light when there is a predetermined voltage difference between the anode layer 1023 and the cathode layer 1021.

The power supply 1024 is used for applying a voltage to the anode layer 1023 and the cathode layer 1021 to form the predetermined voltage difference between the anode layer 1023 and the cathode layer 1021.

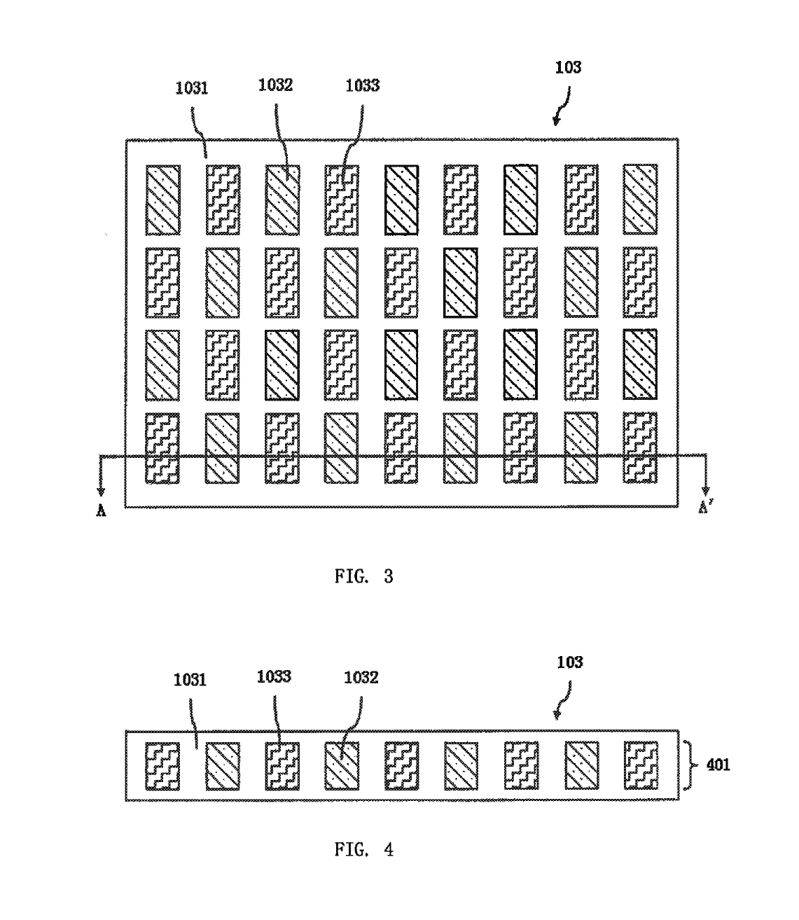

Also referring to FIG. 3, in the embodiment, the photoluminescent layer 103 includes a body material 1031, a photoluminescent green light emitting material 1032, and a photoluminescent red light emitting material 1033.

The body material 1031 is used for allowing the blue light emitted by the electroluminescent blue light emitting material layer 1022 to travel therethrough. The body material 1031, for example, is a transparent material and can be made of transparent plastic.

The photoluminescent green light emitting material 1032 is used for emitting/generating green light when the photoluminescent green light emitting material 1032 is irradiated by the blue light.

The photoluminescent red light emitting material 1033 is used for emitting/generating red light when the photoluminescent red light emitting material 1033 is irradiated by the blue light.

The photoluminescent layer 103 is used for allowing the generated red light and green light and the blue light passing therethrough to mix together to form the white light.

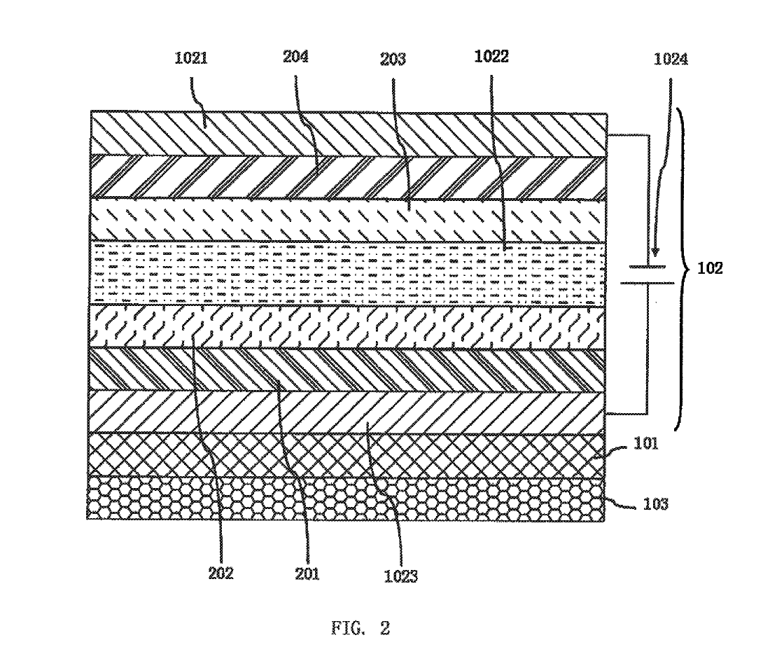

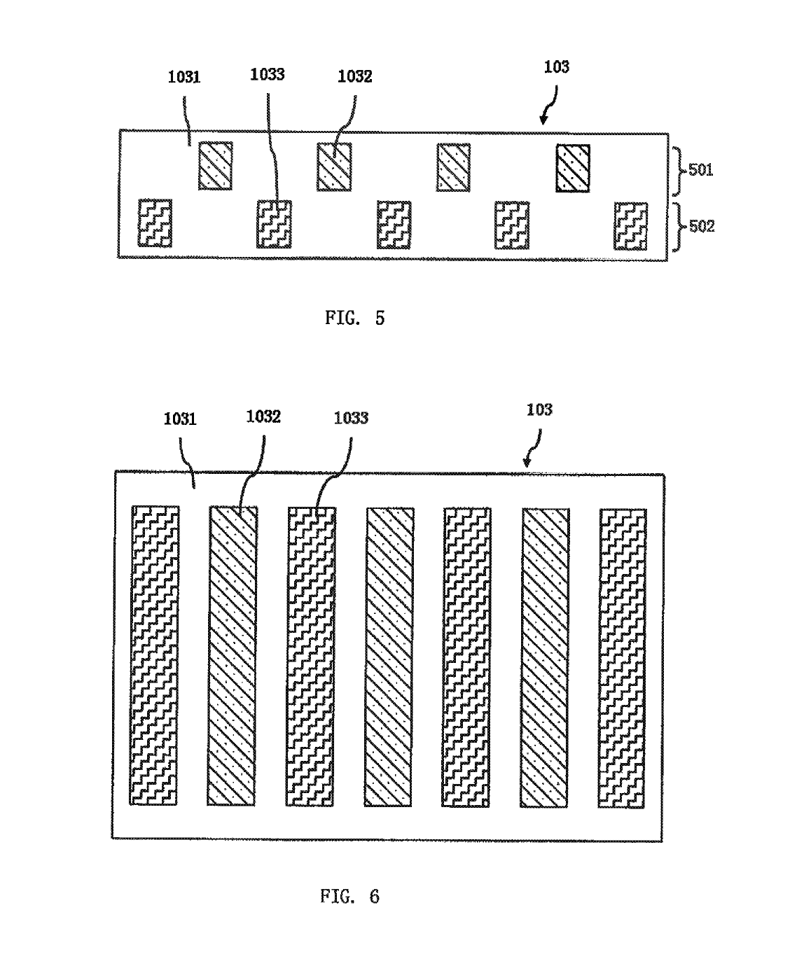

FIG. 3 illustrates a diagram of a first embodiment of the photoluminescent layer 103 in FIG. 1 or FIG. 2. FIG. 4 illustrates a cross section of the first embodiment of the photoluminescent layer 103 taken along line A-A′ of FIG. 3, and FIG. 5 illustrates a cross section of an alternative embodiment of the photoluminescent layer 103.

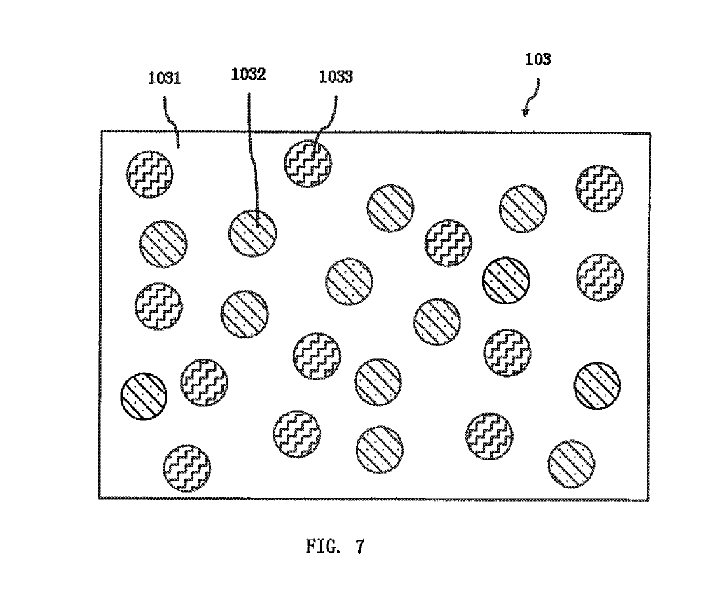

In the present invention, the photoluminescent green light emitting material 1032 is disposed in the body material 1031 in a form of rectangular blocks (as shown in FIG. 3 or FIG. 6) or round granules (as shown in FIG. 7).

Likewise, the photoluminescent red light emitting material 1033 is disposed in the body material 1031 in a form of rectangular blocks or round granules.

For a plane on which the photoluminescent layer 103 is located, a sum of a projected area of the photoluminescent green light emitting material 1032 (blocks or granules) to the plane is a first area, a sum of a projected area of the photoluminescent red light emitting material 1033 (blocks or granules) to the plane is a second area, and a sum of a projected area of the transparent body material 1031 to the plane which equals to an area that the blue light can run through the body material 1031 is a third area.

According to the present invention, any one of the first area, the second area, the third area equals another one of the first area, the second area, the third area multiplies a predetermined ratio, wherein the predetermined ratio is in a range from 90% to 110%. For example, the predetermined ratio can be 90%, 92%, 94%, 95%, 97%, 99%, 100%, 102%, 104%, 105%, 107%, 109%, 110%. Preferably, the ratio is 100% whereby the first area equals the second area which in turn equals the third area.

Referring to FIG. 4, the first embodiment of the photoluminescent layer 103 includes a first stratification 401. The ptolumineseent green light emitting material 1032, the photoluminescent red light emitting material 1033, and the body material 1031 are all located in the first stratification 401.

A combination of the photoluminescent green light emitting material 1032 and the photoluminescent red light emitting material 1033 is arranged in a form of a one-dimensional array (FIG. 6) or a two-dimensional array (FIG. 3).

The photoluminescent green light emitting material 1032 and the photoluminescent red light emitting material 1033 are randomly mixed in the body material 1031.

Alternatively, as shown in FIG. 5, the photoluminescent layer 103 includes a second stratification 501 and a third stratification 502. The photoluminescent green light emitting material 1032 is located in the second stratification 501. The photoluminescent red light emitting material 1033 is located in the third stratification 502. The body material 1031 is disposed in the second stratification 501 and the third stratification 502.

There is a gap between the photoluminescent green light emitting material 1032 and the photoluminescent red light emitting material 1033, and the body material 1031 fills the gap, as shown in FIG. 3 to FIG. 7.

The yield of the green light of the photoluminescent green light emitting material 1032 corresponds to the first area and a first thickness of the stratification (the first stratification 401 or the second stratification 501) in which the photoluminescent green light emitting material 1032 is located. The yield of the red light of the photoluminescent red light emitting material 1033 corresponds to the second area and a second thickness of the stratification (the first stratification 401 or the third stratification 502) in which the photoluminescent red light emitting material 1033 is located. Therefore, the color purity (chromaticity) of the generated white light can be adjusted by adjusting a size of the first area of the photoluminescent green light emitting material 1032 in the photoluminescent layer 103 and a size of the first thickness, and a size of the second area of the photoluminescent red light emitting material 1033 in the photoluminescent layer 103 and a size of the second thickness.

Through the aforementioned technical solution, a white light source in accordance with the present invention is formed which can overcome the disadvantages of the prior art WOLED such as the difficultly controlled concentrations of the doping materials and the complication of the multi-layer structure which can adversely affect generation and the quality of the white light. The technical solution is advantageous for simplifying the manufacturing process while increasing the stability and usage life of the light emitting device.

Refer to FIG. 2, which illustrates a diagram of a second embodiment of the light emitting device of the present invention. The embodiment is similar to the first embodiment, the differences therebetween are as follows:

In the second embodiment, the blue light source generating panel 102 further includes a hole injection layer 201, a hole transport layer 202, an electronic transport layer 203, and an electronic injection layer 204.

The hole injection layer 201 is disposed between the anode layer 1023 and the hole transport layer 202, the hole transport layer 202 is disposed between the hole injection layer 201 and the electroluminescent blue light emitting material layer 1022, the electroluminescent blue light emitting material layer 1022 is disposed between the hole transport layer 202 and the electronic transport layer 203, the electronic transport layer 203 is disposed between the electroluminescent blue light emitting material layer 1022 and the electronic injection layer 204, and the electronic injection layer 204 is disposed between the electronic transport layer 203 and the cathode layer 1021.

In summary, although the present invention has been described in preferred embodiments above, the preferred embodiments described above are not intended to limit the invention. Persons skilled in the art can make various modifications to the present invention without departing from the scope of the invention as defined in the claims.

What is claimed is:

1. A light emitting device comprising:
a substrate including a first surface and a second surface;
a blue light source generating panel disposed on the first surface of the substrate, the blue light source generating panel being used for generating blue light;
a photoluminescent layer disposed on the second surface of the second substrate, the photoluminescent layer being used for generating white light when the photoluminescent layer is irradiated by the blue light;
the blue light source generating panel comprising:
an anode layer;
a cathode layer;
an electroluminescent blue light emitting material layer disposed between the anode layer and the cathode layer, the electroluminescent blue light emitting material layer being used for generating the blue light when there is a predetermined voltage difference between the anode layer and the cathode layer; and
a power supply being used for applying a voltage to the anode layer and the cathode layer to form the predetermined voltage difference between the anode layer and the cathode layer;
the blue light source generating panel further comprising:
a hole injection layer;
a hole transport layer;
an electronic transport layer; and
an electronic injection layer;
wherein the hole injection layer is disposed between the anode layer and the hole transport layer, the electroluminescent blue light emitting material layer is disposed between the hole transport layer and the electronic transport layer, the electronic injection layer is disposed between the electronic transport layer and the cathode layer;
the photoluminescent layer comprises:
a body material used for allowing the blue light being to travel through the body material;
a photoluminescent green light emitting material used for emitting green light when the photoluminescent green light emitting layer is irradiated by the blue light; and
a photoluminescent red light emitting material used for emitting red light when the photoluminescent red light emitting material layer is irradiated by the blue light.

2. The light emitting device of claim 1, wherein the photoluminescent green light emitting material is disposed in the body material in a form of blocks or granules; and
the photoluminescent red light emitting material is disposed in the body material in a form of blocks or granules.

3. The light emitting device of claim 2, wherein the photoluminescent layer comprises:
a first stratification, the photoluminescent green light emitting material, the photoluminescent red light emitting material, and the body material all being located in the first stratification.

4. The light emitting device of claim 3, wherein a combination of the photoluminescent green light emitting material and the photoluminescent red light emitting material is arranged in a form of a one-dimensional array or a two-dimensional array.

5. The light emitting device of claim 4, wherein there is a gap between the photoluminescent green light emitting material and the photoluminescent red light emitting material, and the body material fills the gap.

6. The light emitting device of claim 3, wherein the photoluminescent green light emitting material and the photoluminescent red light emitting material are randomly mixed in the body material.

7. The light emitting device of claim 2, wherein the photoluminescent layer comprises:
a second stratification, the photoluminescent green light emitting material being located in the second stratification; and
a third stratification, the photoluminescent red light emitting material being located in the third stratification;
the body material being disposed in the second stratification and the third stratification.

8. A light emitting device comprising:
a substrate including a first surface and a second surface;
a blue light source generating panel on the first surface of the substrate, the blue light source generating panel being used for generating blue light;
a photoluminescent layer disposed on the second surface of the substrate, the photoluminescent layer being used for generating white light when the photoluminescent layer is irradiated by the blue light.

9. The light emitting device of claim 8, wherein the blue light source generating panel comprises:
an anode layer;
a cathode layer;
an electroluminescent blue light emitting material layer disposed between the anode layer and the cathode layer, the electroluminescent blue light emitting material layer being used for generating the blue light when there is a predetermined voltage difference between the anode layer and the cathode layer; and
a power supply being used for applying a voltage to the anode layer and the cathode layer to form the predetermined voltage difference between the anode layer and the cathode layer.

10. The light emitting device of claim 9, wherein the blue light source generating panel further comprises:
a hole injection layer;
a hole transport layer;
an electronic transport layer; and
an electronic injection layer;
wherein the hole injection layer is disposed between the anode layer and the hole transport layer, the electroluminescent blue light emitting material layer is disposed between the hole transport layer and the electronic transport layer, the electronic injection layer is disposed between the electronic transport layer and the cathode layer.

11. The light emitting device of claim 8, wherein the photoluminescent layer comprises:
a body material used for enabling the blue light emitted from the blue light source generating panel to pass therethrough;
a photoluminescent green light emitting material used for emitting green light when the photoluminescent green light emitting material is irradiated by the blue light; and
a photoluminescent red light emitting material used for emitting red light when the photoluminescent red light emitting material is irradiated by the blue light.

12. The light emitting device of claim 11, wherein the photoluminescent layer is used for allowing the generated red light and green light and the blue light passing therethrough to mix to form the white light.

13. The light emitting device of claim 11, wherein the photoluminescent green light emitting material is disposed in the body material in a form of blocks or granules; and
the photoluminescent red light emitting material is disposed in the body material in a form of blocks or granules.

14. The light emitting device of claim 13, wherein the photoluminescent layer comprises:
a first stratification, the photoluminescent green light emitting material, the photoluminescent red light emitting material and the body material all being located in the first stratification.

15. The light emitting device of claim 14, wherein a combination of the photoluminescent green light emitting material and the photoluminescent red light emitting material is arranged in a form of a one-dimensional array or a two-dimensional array.

16. The light emitting device of claim 15, wherein there is a gap between the photoluminescent green light emitting material and the photoluminescent red light emitting material, and the body material fills the gap.

17. The light emitting device of claim 14, wherein the photoluminescent green light emitting material and the photoluminescent red light emitting material are randomly mixed in the body material.

18. The light emitting device of claim 13, wherein the photoluminescent layer comprises:
a second stratification, the photoluminescent green light emitting material being located in the second stratification; and
a third stratification, the photoluminescent red light emitting material being located in the third stratification;
the body material being disposed in the second stratification and the third stratification.

19. The light emitting device of claim 11, wherein for a plane on which the photoluminescent layer is located, a sum of a projected area of the photoluminescent green light emitting material to the plane is a first area, a sum of a projected area of the photoluminescent red light emitting material to the plane is a second area, a sum of a projected area of the body material to the plane is a third area; and
any one of the first area, the second area and the third area equals another one of the first area, the second area and the third area multiplies a predetermined ratio, the predetermined ratio being in a range from 90% to 110%.

20. The light emitting device of claim 19, wherein the first area equals the second area which in turn equal the third area.
